(19) United States
(12) Patent Application Publication
(10) Pub. No.: US 2010/0138709 A1
(43) Pub. Date: Jun. 3, 2010

(54) METHOD AND APPARATUS FOR DELAY FAULT COVERAGE ENHANCEMENT

(76) Inventors: Laung-Terng WANG, Sunnyvale, CA (US); Michael S. Hsiao, Blacksburg, VA (US); Hao-Jan Chao, Taoyuan City (TW); Zhigang Jiang, Burlingame, CA (US); Shianling Wu, Prineston Sunotion, NJ (US); Jianping Yan, Miepitas, CA (US)

Correspondence Address: BACON & THOMAS, PLLC, 625 SLATERS LANE, FOURTH FLOOR, ALEXANDRIA, VA, 22314-1176, US

(21) Appl. No.: 12/554,437

(22) Filed: Sep. 4, 2009

Related U.S. Application Data
(60) Provisional application No. 61/193,008, filed on Oct. 22, 2008.

(51) Int. Cl. G01R 31/3177; G06F 11/27

(52) U.S. Cl. 714/731; 714/E11.169

(57) ABSTRACT

A hybrid clocking scheme for simultaneously detecting a b-cycle path-delay fault in a b-cycle (false) path and a c-cycle path-delay fault in a c-cycle (false) path using at least n+1 at-speed clock pulses during a capture operation in a clock domain in a scan design or a scan-based BIST design, where 1<=b<=c<=n. The scan design or BIST design includes multiple scan chains, each scan chain comprising multiple scan cells coupled in series. The design includes one or more clock domains each running at its intended operating frequency or at-speed. The hybrid clocking scheme comprises at least one at-speed shift clock pulse or one at-speed capture clock pulse immediately followed by at least two at-speed capture clock pulses during the capture operation to simultaneously detect the b-cycle path-delay fault and the c-cycle path-delay fault within the clock domain.

### RELATED APPLICATION DATA

This application claims the benefit of U.S. Provisional Application No. 69/193,008 filed Oct. 22, 2008, which is hereby incorporated by reference.

### TECHNICAL FIELD

The present invention generally relates to the field of logic design and test using design-for-test (DFT) techniques. Specifically, the present invention relates to the field of logic test and diagnosis for integrated circuits using scan or built-in self-test (BIST) techniques.

### BACKGROUND

As the semiconductor manufacturing technologies move into the nanometer era, delay fault testing has emerged as one of the most important test techniques in screening defective chips caused by timing delay defects in manufactured devices. Two basic capture-clocking schemes using launch-on-shift (LOS) and launch-on-capture (LOC) are commonly used to detect delay faults in a scan design or a scan-based built-in self-test (BIST) design. The scan design or BIST design contains one or more scan cells coupled in series to form one or more scan chains. A scan cell is a reconfigured storage element from a D flip-flop, a latch, or a pulse latch. When the scan cell is operated in normal mode, it acts as a normal storage element. When the scan cell is operated in scan mode, it allows shifting-in data from an external source and shifting-out its output response to the external source for analysis. Oftentimes, a scan enable signal SE is used to indicate the scan mode when SE is set to 1, and the normal mode when SE is set to 0.

Typically, using the LOS scheme to detect delay faults in a scan design or BIST design can achieve higher fault coverage than using the LOC scheme. The drawbacks of the LOS clocking scheme are that LOS can cause unwanted over-testing because more false paths may be exercised, and incur higher implementation cost because the scan enable signal SE in each clock domain must be operated at-speed. This is in sharp contrast to LOC in which only a slow-speed, global scan enable signal GSE to drive the SEs in all clock domains is needed.

Current solutions to increasing the delay fault coverage of a design are typically done by activating multiple capture cycles or utilizing a combination of both LOS and LOC clocking techniques. The solution using multiple activation cycles, as described by Zhang et al. (2006), is to apply more-than-one capture clock pulses (cycles) in LOC or LOS. The burst mode as described by Nadeau-Dostie et al. (2008) comprises applying two or more at-speed shift clock pulses immediately followed by one at-speed capture clock pulse. The purposes of applying two or more at-speed shift clock pulses prior to the at-speed capture clock pulse are to avoid clock stretching and test multi-cycle paths and false paths. Clock stretching adversely increases the clock's cycle time (e.g., from 3.2 ns to 3.7 ns) and is caused by the sudden voltage drop due to di/dt effects when a pure LOS or LOC clocking scheme is used. Nadeau-Dostie et al. (2008) illustrated that the stretched cycle time is reduced by an order of magnitude (56% to 4.5%) when three launch (shift) cycles instead of one were used prior to the capture cycle. Multi-cycle paths and false paths are paths with multi-cycle delays within a clock domain or across two clock domains. Within each clock domain, multi-cycle paths are sometimes used, instead of pipelining, to implement functions at a lower cost. False paths are often present across asynchronous clock domains which must be correctly handled to avoid false timing violations.

The solution in mixing the LOS and LOC schemes, as described by Zhang et al. (2006) and Park and McCluskey (2008), is mainly to employ the LOS-followed-by-LOC or LOC-followed-by-LOS clocking scheme. Another solution as described by Ahmed and Tehranipoor (2006) is to partition the design into two segments and then to apply LOS to one segment of the design and LOC to the other segment of the design. For multiple clock domains, the staggered LOC clocking scheme or the staggered LOS clocking scheme that places clock pulses in a sequential order, as described by Wang et al. in U.S. Pat. Nos. 6,954,887 and 7,007,213, can allow at-speed delay fault testing of synchronous and asynchronous clock domains while at the same time reducing the number of test patterns for testing a scan design or a BIST design. However, all of these solutions still do not yield sufficient delay fault coverage because when the design contains multi-cycle paths or multi-cycle false paths, these paths must be tested separately. A multi-cycle (false) path is a combinational (false) path bounded by a source flip-flop and a destination flip-flop where data originates from the source flip-flop can only propagate to the destination flip-flop in multiple cycles. An n-cycle path-delay fault is a delay fault in an n-cycle path, where n>=1. Such approach may further increase test application time and test data volume when performing a comprehensive testing of the scan or BIST design.

### SUMMARY

Accordingly, there is a need to develop an improved method and apparatus for delay fault testing that simultaneously detecting at least a b-cycle path-delay fault and a c-cycle path-delay fault using a test clock comprising n+1 at-speed clock pulses during the capture operation, where 1<=b<=c<=n.

To detect a delay fault (which is a 1-cycle path-delay fault) in a clock domain, a test stimulus is shifted into all scan cells in the clock domain during a shift operation. The shift frequency of the test clock, CK, which drives the clock domain may be at a reduced clock speed (called slow-speed) or at the clock domain's intended operating speed (called at-speed). During the shift operation, the circuit is operated in scan mode. The scan enable signal, SE, which is often used to control all scan cells may be set to 1 to indicate the scan mode operation. Then, at least two consecutive at-speed clock pulses are applied to the test clock, CK, to capture the results into the scan cells in response to the stimulus during the capture operation. The capture frequency of the test clock, CK, must be at the clock domain's intended operating speed (or at-speed). During the capture operation, the circuit is operated in normal mode. The scan enable signal, SE, may be set to 1 when supplying an at-speed shift clock pulse or 0 when supplying an at-speed capture clock pulse, depending on needs, to indicate the capture operation. The output response is then shifted out for analysis to determine whether the delay fault is detected.

To simultaneously detect a b-cycle path-delay fault and a c-cycle path-delay fault, the method we propose in this invention is to apply an ordered sequence of clock pulses using a hybrid clocking scheme to the test clock that during a capture operation comprises at least i at-speed shift clock pulses immediately followed by at least n+1−i at-speed capture clock pulses, where 0<=i<n and where 1<=b<=c<=n; the consecutive b−1 and c−1 at-speed clock pulses controlling the b-cycle path and c-cycle path are suppressed for detecting the b-cycle path-delay fault and the c-cycle path-delay fault, respectively. The hybrid clock pulses can be applied to one clock domain at a time or to a plurality of clock domains simultaneously, in a staggered manner, or in a one-hot manner. Also, one or more consecutive at-speed or slow-speed shift clock pulses are applied prior to the hybrid clock pulses to avoid clock stretching.

A delay fault may be a transition fault, a path-delay fault, or a bridging-transition fault. The ordered sequence of clock pulses may further detect stuck-at faults, IDDQ (IDD quiescent current) faults, and bridging faults in the clock domain. The ordered sequence of clock pulses may further comprise disabling selected clock pulses in the test clock to facilitate fault diagnosis or for low-power testing.

Also, if the hybrid clocking scheme does not include any at-speed shift clock pulse when testing multiple clock domains in the design, a global scan enable signal GSE running at slow-speed may be used to drive all scan enable signals, SEs, each controlling a clock domain. This will significantly reduce physical implementation efforts.

### THE BRIEF DESCRIPTION OF DRAWINGS

The above and other objects, advantages and features of the invention will become more apparent when considered with the following specification and accompanying drawings wherein:

FIGS. 1A and 1B show two prior art design waveforms using the basic LOS and LOC at-speed clocking schemes for detecting intra-clock-domain faults in a scan design or a scan-based BIST design, respectively;

FIG. 2 shows an embodiment of a 1-shift-2-capture hybrid clocking scheme, in accordance with the present invention, for simultaneously detecting intra-clock-domain delay faults, 2-cycle path-delay faults, and 2-cycle false paths in a clock domain in a scan design or a scan-based BIST design;

FIG. 3 shows an embodiment of a 2-shift-2-capture hybrid clocking scheme, in accordance with the present invention, for simultaneously detecting intra-clock-domain delay faults, 2-cycle and 3-cycle path-delay faults, and 2-cycle and 3-cycle false paths in a clock domain in a scan design or a scan-based BIST design;

FIG. 4 shows an embodiment of a 3-capture clocking scheme, in accordance with the present invention, for simultaneously detecting intra-clock-domain delay faults, 2-cycle path-delay faults, and 2-cycle false paths in a clock domain in a scan design or a scan-based BIST design;

FIG. 5 shows an embodiment of a hybrid clocking scheme, in accordance with the present invention, for detecting intra-clock-domain faults within each clock domain and inter-clock-domain faults across two clock domains in a scan design or a scan-based BIST design.

### DETAILED DESCRIPTION OF THE INVENTION

The following description is presently contemplated as the best mode of carrying out the present invention. This description is not to be taken in a limiting sense but is made merely for the purpose of describing the principles of the invention. The scope of the invention should be determined by referring to the appended claims.

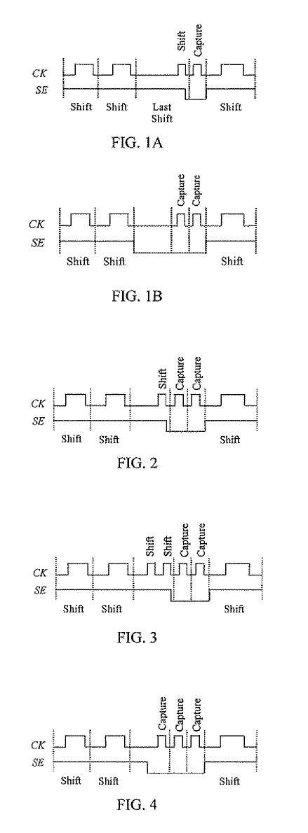

FIGS. 1A and 1B show the prior art design waveforms using the basic LOS and LOC at-speed clocking schemes for testing intra-clock-domain delay faults in a clock domain in a scan design or a scan-based BIST design, respectively. Assume the clock domain is controlled by a clock signal CK. An intra-clock-domain delay fault resides in the clock domain and gets detected in the same clock domain.

During the shift operation, a series of shift clock pulses are applied to CK to shift in a test stimulus to all scan cells in all clock domains when the scan enable signal SE is set to 1. During the capture operation, an at-speed launch clock pulse followed by an at-speed capture clock pulse are required to detect intra-clock-domain delay faults. During capture, LOS (as shown in FIG. 1A) uses the “last shift” clock pulse (when SE=1) followed immediately by a capture clock pulse (when SE=0) to launch a transition and capture its output response, respectively. LOC (as shown in FIG. 1B) uses two consecutive capture clock pulses during the capture operation (when SE=0) to launch the transition and capture the output response, respectively. During the capture operation, both launch and capture clock pulses must be running at the domain's operating frequency or at-speed in order to detect delay faults. The main difference between LOS and LOC is that LOS requires the domain's scan enable signal SE to switch its value between the launch and capture clock pulses at-speed, making SE act as a clock signal. Also, if the LOC clocking scheme is used for testing multiple clock domains in the design, then a global scan enable signal GSE running at slow-speed may be used to drive all SEs each controlling a clock domain. This will significantly reduce LOC's physical implementation efforts.

FIG. 2 shows an embodiment of a 1-shift-2-capture hybrid clocking scheme, in accordance with the present invention, for simultaneously detecting intra-clock-domain delay faults, 2-cycle path-delay faults, and 2-cycle false paths in a clock domain in a scan design or a scan-based BIST design. An intra-clock-domain fault resides in the clock domain and gets detected in the same clock domain. In this embodiment, during scan shift, a plurality of shift clock pulses is applied to the clock domain. The shift speed can be performed at the domain's intended frequency (at-speed) or at a reduced clock speed. During capture, an at-speed “last shift” clock pulse (when SE=1) followed by two at-speed capture clock pulses (when SE=0) are applied to the clock domain.

The main advantage of this 1-shift-2-capture hybrid clocking scheme is that since the very “last shift” and first capture clock pulses constitute an LOS test set, the test set may detect more intra-clock-domain delay faults than using the conventional LOC clocking scheme alone. Also, since the first capture clock pulse followed by the second capture clock pulse constitute an LOC test set, the test set may further detect additional intra-clock-domain faults, which may not be detected by the conventional LOS clocking scheme alone. Hence, this 1-shift-2-capture hybrid clocking scheme may detect more intra-clock-domain delay faults than the conventional LOS or LOC clocking scheme alone, or an enhanced LOC-only scheme using multiple activation cycles.

In addition, the scheme may also detect 2-cycle path-delay faults in 2-cycle paths and 2-cycle false paths. A 2-cycle path-delay fault is a delay fault in a combinational logic path that originates from a source flip-flop and gets detected by a destination flip-flop in two at-speed clock cycles or clock pulses. This fault may be detected when the first capture clock pulse controlling the source flip-flop that drives the targeted 2-cycle path is disabled or the value of the source flip-flop that drives the targeted 2-cycle path is held at its original state when the first capture clock pulse is activated.

FIG. 3 shows an embodiment of a 2-shift-2-capture hybrid clocking scheme, in accordance with the present invention, for simultaneously detecting intra-clock-domain delay faults, 2-cycle and 3-cycle path-delay faults, and 2-cycle and 3-cycle false paths in a clock domain in a scan design or a scan-based BIST design. The 2-cycle path-delay faults and 2-cycle false paths may be detected using the same approach as described in FIG. 2. A 3-cycle path-delay fault or 3-cycle false path is a delay fault in a combinational logic path that originates from a source flip-flop and gets detected by a destination flip-flop after three at-speed clock cycles or clock pulses. In this embodiment, during capture, CK consists of two at-speed shift clock pulses (when SE=1) and two at-speed capture clock pulses (when SE=0). The 3-cycle path-delay fault may be detected by the 2-shift-2-capture hybrid clocking scheme when the second shift and first capture clock pulses controlling the source flip-flop that drives the targeted 3-cycle delay path is disabled or the value of the source flip-flop that drives the targeted 3-cycle delay path is held at its original state when the second shift and first capture clock pulses are activated.

To summarize, to detect an n-cycle path-delay fault or an n-cycle false path simultaneously this means one may apply at least an (n−1)-shift-2-capture hybrid clocking scheme during capture. Alternatively, one may apply at least a 1-shift-n-capture hybrid clock scheme, or an i-shift-(n+1−i)-capture hybrid clocking scheme, where 0≦i≦n.

Thus, to simultaneously detect a b-cycle path-delay fault and a c-cycle path-delay fault when the test clock comprises at least n+1 clock pulses during the capture operation, the consecutive b−1 and c−1 at-speed clock pulses prior to the last at-speed capture clock pulse that drive the b-cycle path and c-cycle path are suppressed or controlled to hold the state of the two paths' source flip-flops, respectively, where 1<=b<=c<=n.

FIG. 4 shows an embodiment of a 3-capture clocking scheme, in accordance with the present invention, for simultaneously detecting intra-clock-domain delay faults, 2-cycle path-delay faults, and 2-cycle false paths in a clock domain in a scan design or a scan-based BIST design. An intra-clock-domain fault resides in the clock domain and gets detected in the same clock domain. In this embodiment, during scan shift, a plurality of shift clock pulses is applied to the clock domain. The shift speed can be performed at the domain's intended frequency (at-speed) or at a reduced clock speed. During capture, three at-speed capture clock pulses (when SE=0) are applied to the clock domain.

The main advantage of this 3-capture (or 0-shift-3-capture) clocking scheme is that the scan enable signal, SE, can operate at slow-speed. Thus, when the 3-capture clocking scheme is used for testing multiple clock domains in the design, a global scan enable signal GSE running at slow-speed may be used to drive all SEs each controlling a clock domain. This will significantly reduce physical implementation efforts.

In the 3-capture clocking scheme, the first two capture clock pulses constitute an LOC test set. Since the third capture clock pulse followed by the second capture clock pulse constitute another LOC test set, the test set may further detect additional intra-clock-domain faults, which may not be detected by the conventional LOC clocking scheme alone. Hence, this 3-capture hybrid clocking scheme may detect more intra-clock-domain delay faults than the conventional LOC clocking scheme alone. In addition, the scheme may also detect 2-cycle path-delay faults and 2-cycle false paths. A 2-cycle path-delay fault or 2-cycle false path is a delay fault in a combinational logic path that originates from a source flip-flop and gets detected by a destination flip-flop after two at-speed clock cycles or clock pulses. This fault may be detected by the destination flip-flop when the second capture clock pulse controlling the source flip-flop that drives the targeted 2-cycle path is disabled or the value of the source flip-flop that drives the targeted 2-cycle path is held at its original state when the second capture clock pulse is activated.

To summarize, to detect an n-cycle path-delay fault or an n-cycle false path simultaneously further means one may apply at least an (n+1)-capture hybrid clocking scheme during capture.

Thus, to simultaneously detect a b-cycle path-delay fault and a c-cycle path-delay fault when the test clock comprises at least n+1 clock pulses during the capture operation, the consecutive b−1 and c−1 at-speed clock pulses prior to the last at-speed capture clock pulse that drive the b-cycle path and c-cycle path are selectively suppressed or controlled to hold the state of the two paths' source flip-flops, respectively, where 1<=b<=c<=n.

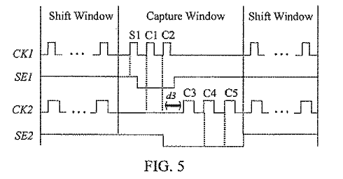

FIG. 5 shows an embodiment of a hybrid clocking scheme, in accordance with the present invention, for detecting intra-clock-domain faults within each clock domain and inter-clock-domain faults across the two clock domains in a scan design or a scan-based BIST design. An inter-clock-domain fault resides across the clock domain and gets detected at a receiving clock domain. In this embodiment, CK1 and CK2 may be triggered in a staggered manner, in a one-hot manner, or simultaneously.

Clock CK1 may comprise an ordered sequence of clock pulses as described in FIGS. 2 to 4. In FIG. 5, CK1 comprises one at-speed shift clock pulse (S1) followed by two at-speed capture pulses (C1 and C2). Clock CK2 may selectively comprise two or more at-speed capture clock pulses or one or more at-speed shift clock pulses immediately followed by one or more at-speed capture clock pulses. In this figure, CK2 comprises three at-speed capture clock pulses (C3, C4, and C5). By adjusting the delay d3 between the two clock domains properly across the inter-domain logic, the staggered clocking scheme allows propagation of data from one clock domain to the other clock domain, and thus can detect the inter-clock-domain stuck-at and delay faults residing between the two clock domains.

If all clock pulses in CK1 (or CK2) in the capture window are disabled when testing CK2 (or CK1), the one-hot clocking scheme can detect intra-clock-domain stuck-at and delay faults as well as inter-clock-domain stuck-at faults. This one-hot scheme does not need to adjust d3, and the test patterns generated are guaranteed to be hazard-free. It is also possible to test both clock domains simultaneously without adjusting d3. In this case, the simultaneous clocking scheme can only detect intra-clock-domain stuck-at and delay faults; neither inter-clock-domain stuck-at faults nor delay faults can be detected. Unknown values may be generated in the test patterns for those signals across the two clock domains. Each of the staggered clocking scheme, one-hot clocking scheme, and simultaneous clocking scheme is applicable for testing both synchronous and asynchronous clock domains. Two clock domains are said to be synchronous if one of their shift or capture clock pulses during the capture operation can be precisely aligned with each other. This only happens when the frequency of one clock domain is a multiple integer of that of the other clock domain, e.g., 100 MHz and 50 MHz. Otherwise, the two clock domains are said to be asynchronous.

Alternatively, an aligned clocking scheme may be used to test two synchronous clock domains. In this case, the last capture clock pulse in the capture window in both clock domains may be aligned precisely. In a broader sense, any shift or capture clock pulse in the capture window in both clock domains may be aligned precisely to perform the capture operation.

To detect a 2-cycle intra-clock-domain delay fault in the clock domain controlled by CK1, the first capture clock pulse C1 in CK1 controlling the source flip-flop may be disabled or the value of the source flip-flop that drives the targeted 2-cycle delay path may be held at its original state when C1 is activated. To detect a 2-cycle intra-clock-domain delay fault in the clock domain controlled by CK2, the second capture clock pulse C4 in CK2 controlling the source flip-flop may be disabled or the value of the source flip-flop that drives the targeted 2-cycle delay path may be held at its original state when C4 is activated. Therefore, the capture waveform given in the capture window in FIG. 5 may also detect intra-clock-domain delay faults as well as 2-cycle path-delay faults and 2-cycle false paths within each clock domain simultaneously.

Having thus described presently preferred embodiments of the present invention, it can now be appreciated that the objectives of the invention have been fully achieved. And it will be understood by those skilled in the art that many changes in construction & circuitry, and widely differing embodiments & applications of the invention will suggest themselves without departing from the spirit and scope of the present invention. The disclosures and the description herein are intended to be illustrative and are not in any sense limitation of the invention, more preferably defined in scope by the following claims.

1. A method for providing an ordered sequence of n+1 clock pulses to a test clock for detecting a b-cycle path-delay fault in a b-cycle (false) path and a c-cycle path-delay fault in a c-cycle (false) path simultaneously, where 1<=b<=c<=n, in a clock domain in a scan design or a scan-based built-in self-test (BIST) design during test, the test clock driving the clock domain which contains one or more scan cells coupled in series, the test clock comprising at least a shift clock pulse and at least a capture clock pulse, each shift clock pulse running selectively at a selected reduced shift frequency (called slow-speed) or at the clock domain's intended operating frequency (called at-speed) in scan mode, each capture clock pulse running at-speed in normal mode; said method comprising:
(a) Applying to the test clock one or more slow-speed or at-speed shift clock pulses to shift-in a test stimulus to all said scan cells in said clock domain, during a shift operation;
(b) Applying said ordered sequence of clock pulses to the test clock that comprises at least i at-speed shift clock pulses immediately followed by at least n+1−i at-speed capture clock pulses to capture the results into all said scan cells in response to said test stimulus, where 0<=i<n, during a capture operation; wherein when detecting the b-cycle path-delay fault and the c-cycle path-delay fault simultaneously, the consecutive b−1 and c−1 at-speed shift or capture clock pulses prior to the last at-speed capture clock pulse that drive the b-cycle (false) path and the c-cycle (false) path are selectively suppressed or controlled to hold the state of the two paths' source flip-flops to ensure the correct capture of the output response, respectively; and
(c) Applying to the clock domain one or more slow-speed or at-speed shift clock pulses to shift-out the output response of all said scan cells in said clock domain for analysis, during the shift operation.

2. The method of claim 1, wherein said consecutive b−1 and c−1 at-speed shift or capture clock pulses prior to the last at-speed capture clock pulse are programmable for performing said capture operation.

3. The method of claim 1, wherein said ordered sequence of clock pulses further including one or more consecutive second at-speed or slow-speed shift clock pulses prior to said order sequence of clock pulses to avoid clock stretching.

4. The method of claim 1, further comprising providing a scan enable signal SE for controlling said clock domain; wherein said scan enable signal SE is used to switch said shift operation and said capture operation; and wherein said scan enable signal SE is selectively generated internally or controlled externally, and can be selectively operated at said clock domain's intended clock speed or at a reduced clock speed.

5. The method of claim 4, wherein said scan enable signal SE is used to switch said shift operation and said capture operation further comprises selectively operating said scan enable signal SE in said clock domain at said clock domain's intended clock frequency, when said test clock controlling said clock domain contains one or more said at-speed shift clock pulses, during said capture operation.

6. The method of claim 4, wherein said providing a scan enable signal SE for controlling said clock domain further comprises using a global scan enable signal GSE to drive said scan enable signal SE, when said clock domain controlled by said scan enable signal SE does not contain any said at-speed shift clock pulse during said capture operation; wherein said global scan enable signal GSE may operate at a reduced clock speed.

7. The method of claim 1, wherein said applying said ordered sequence of clock pulses further comprises applying a second selected ordered sequence of clock pulses to a second clock domain selectively in a staggered manner, in a one-hot manner, in a simultaneous manner, or in an aligned manner, for detecting a delay fault in said second clock domain.

8. The method of claim 7, wherein said applying a second selected ordered sequence of clock pulses to a second clock domain further comprises selectively applying two or more at-speed capture clock pulses or applying one or more at-speed shift clock pulses immediately followed by one or more at-speed capture clock pulses.

9. The method of claim 1, wherein said applying an ordered sequence of clock pulses further comprises disabling selected clock pulses in said test clock in said clock domain to facilitate fault diagnosis or for low-power testing.

10. The method of claim 1, wherein said scan cell is reconfigured from a D flip-flop, a latch, or a pulse latch; wherein said delay fault is a transition fault, a path-delay fault, or a bridging-transition fault; and wherein said ordered sequence of clock pulses further detects stuck-at faults, IDDQ (IDD quiescent current) faults, and bridging faults in said clock domain.

11. An apparatus for providing an ordered sequence of n+1 clock pulses to a test clock for detecting a b-cycle path-delay fault in a b-cycle (false) path and a c-cycle path-delay fault in a c-cycle (false) path simultaneously, where 1<=b<=c<=n, in a clock domain in a scan design or a scan-based built-in self-test (BIST) design during test, the test clock driving the clock domain which contains one or more scan cells coupled in series, the test clock comprising at least a shift clock pulse and at least a capture clock pulse, each shift clock pulse running selectively at a selected reduced shift frequency (called slow-speed) or at the clock domain's intended operating frequency (called at-speed) in scan mode, each capture clock pulse running at-speed in normal mode; said apparatus comprising:
(a) A first hardware for applying to the test clock one or more slow-speed or at-speed shift clock pulses to shift-in a test stimulus to all said scan cells in said clock domain, during a shift operation;
(b) A second hardware for said ordered sequence of clock pulses to the test clock that comprises at least i at-speed shift clock pulses immediately followed by at least n+1−i at-speed capture clock pulses to capture the results into all said scan cells in response to said test stimulus, where 0<=i<n, during a capture operation; wherein when detecting the b-cycle path-delay fault and the c-cycle path-delay fault simultaneously, the consecutive b−1 and c−1 at-speed shift or capture clock pulses next to the last at-speed capture clock pulse that drive the b-cycle (false) path and the c-cycle (false) path are selectively suppressed or controlled to hold the state of the two path's source flip-flops to ensure the correct capture of the output response, respectively; and
(c) A third hardware for applying to the clock domain one or more slow-speed or at-speed shift clock pulses to shift-out the output response of all said scan cells in said clock domain for analysis, during the shift operation.

12. The apparatus of claim 11, wherein said second hardware further includes means to program said consecutive b−1 and c−1 at-speed shift or capture clock pulses prior to the last at-speed capture clock pulse for performing said capture operation.

13. The apparatus of claim 11, wherein said second hardware further includes means to generate one or more consecutive second at-speed or slow-speed shift clock pulses prior to said order sequence of clock pulses to avoid clock stretching.

14. The apparatus of claim 11, further comprising a fourth hardware for providing a scan enable signal SE for controlling said clock domain; wherein said scan enable signal SE is used to switch said shift operation and said capture operation; and wherein said scan enable signal SE is selectively generated internally or controlled externally, and can be selectively operated at said clock domain's intended clock speed or at a reduced clock speed.

15. The apparatus of claim 14, wherein said scan enable signal SE is used to switch said shift operation and said capture operation further comprises selectively operating said scan enable signal SE in said clock domain at said clock domain's intended clock frequency, when said test clock controlling said clock domain contains one or more said at-speed shift clock pulses, during said capture operation.

16. The apparatus of claim 14, wherein said providing a scan enable signal SE for controlling said clock domain further comprises using a global scan enable signal GSE to drive said scan enable signal SE, when said clock domain controlled by said scan enable signal SE does not contain any said at-speed shift clock pulse during said capture operation; wherein said global scan enable signal GSE may operate at a reduced clock speed.

17. The apparatus of claim 11, wherein said applying said ordered sequence of clock pulses further comprises applying a second selected ordered sequence of clock pulses to a second clock domain selectively in a staggered manner, in a one-hot manner, in a simultaneous manner, or in an aligned manner, for detecting a delay fault in said second clock domain.

18. The apparatus of claim 17, wherein said applying a second selected ordered sequence of clock pulses to a second clock domain further comprises selectively applying two or more at-speed capture clock pulses or applying one or more at-speed shift clock pulses immediately followed by one or more at-speed capture clock pulses.

19. The apparatus of claim 11, wherein said applying an ordered sequence of clock pulses further comprises disabling selected clock pulses in said test clock in said clock domain to facilitate fault diagnosis or for low-power testing.

20. The apparatus of claim 11, wherein said scan cell is reconfigured from a D flip-flop, a latch, or a pulse latch; wherein said delay fault is a transition fault, a path-delay fault, or a bridging-transition fault; and wherein said ordered sequence of clock pulses further detects stuck-at faults, IDDQ (IDD quiescent current) faults, and bridging faults in said clock domain.
